(19) United States
(12) Patent Application Publication
(10) Pub. No.: US 2025/0102651 A1
(43) Pub. Date: Mar. 27, 2025

(54) HIDDEN ULTRASONIC SENSING SYSTEMS SUITABLE FOR ADVANCED DRIVER ASSISTANCE

(71) Applicant: SEMICONDUCTOR COMPONENTS INDUSTRIES, LLC, Scottsdale, AZ (US)

(72) Inventor: Marek HUSTAVA, Bratislava (SK)

(73) Assignee: SEMICONDUCTOR COMPONENTS INDUSTRIES, LLC, Scottsdale, AZ (US)

(21) Appl. No.: 18/631,649

(22) Filed: Apr. 10, 2024

Related U.S. Application Data
(60) Provisional application No. 63/585,120, filed on Sep. 25, 2023.

(51) Int. Cl. G01S 7/521; G01S 15/10; G01S 15/87; G01S 15/931

(52) U.S. Cl. CPC G01S 7/521; G01S 15/10; G01S 15/876; G01S 2015/938

(57) ABSTRACT

Illustrative sensor controllers, sensors, sensing systems, and sensing methods, may enable cost-efficient implementation of ADAS (advanced driver-assistance system) features with hidden sensors. As one example, an illustrative sensing method includes: transmitting an acoustic burst through a surface over an ultrasonic transducer; receiving an acoustic signal with a MEMS (micro-electromechanical systems) microphone, the MEMS microphone representing the acoustic signal as an electrical receive signal; and processing the electrical receive signal to detect a reflection of the acoustic burst.

### CROSS-REFERENCE TO RELATED APPLICATIONS

The present application claims priority to Provisional U.S. Application 63/585,120 filed 2023 Sep. 25 naming inventor Marek Hustava. The foregoing application is hereby incorporated herein by reference in its entirety.

### BACKGROUND

Modern automobiles are equipped with an impressive number and variety of sensors which enable a startling variety of desirable features including “kick to open”, park assist, automated parking, door protection, passenger detection, intrusion monitoring, and blind spot monitoring, to name just a few. These illustrative features can each be enabled with suitably placed ultrasonic sensors, for example. Design aesthetics often call for such sensors to be made as unobtrusive as possible, e.g., by hiding the sensors behind surfaces that are unblemished by openings, mesh, acoustic windows, doors, inserts, or any other visible or tactile indications of a hidden sensor or concealed cavity. (An acoustic window is a region of the surface that is substantially thinned or otherwise configured differently, e.g., with different dimensions or material properties, to better convey acoustic bursts.) Examples of unblemished surfaces may include the car's outer skin (e.g., hood, trunk lid, doors, body panels, bumper shrouds) and interior surfaces (e.g., dashboard, ceiling, inner door panels).

While hidden ultrasonic sensors have been shown to function adequately, their function may be adversely affected by the overlying surface. One issue is attenuation of the acoustic bursts, which can reduce the maximum sensing range. Another issue is extended reverberation of the piezoelectric element caused by mechanical coupling between the element and the overlying surface, which can prevent detection of nearby objects. One proposed solution to these issues employs an impedance matching layer to reduce attenuation and an additional layer or structure of damping material, but the cost for the proposed solution is expectedly to make it economically infeasible for automotive applications.

### SUMMARY

Accordingly, there are disclosed herein illustrative sensor controllers, sensors, sensing systems, and sensing methods that at least partly address the issues identified above. As one example, an illustrative sensing method includes: transmitting an acoustic burst through a surface over an ultrasonic transducer; receiving an acoustic signal with a MEMS (micro-electromechanical systems) microphone, the MEMS microphone representing the acoustic signal as an electrical receive signal; and processing the electrical receive signal to detect a reflection of the acoustic burst.

An illustrative sensor controller includes: a transmitter configured to drive an ultrasonic transducer to transmit an acoustic burst; a receiver configured to receive an electrical receive signal from a MEMS microphone representing an acoustic signal; and core logic configured to process the electrical receive signal to detect a reflection of the acoustic burst.

An illustrative ADAS (advanced driver-assistance system) includes: an ultrasonic transducer configured to transmit an acoustic burst through a surface over the ultrasonic transducer; a MEMS (micro-electromechanical systems) microphone configured to convert a received acoustic signal into an electrical receive signal; and a controller configured to detect a reflection of the acoustic burst based on the electrical receive signal.

Each of the foregoing examples can be employed individually or in conjunction and may include one or more of the following features in any suitable combination: 1. the surface has no opening or acoustic window for conveying the acoustic burst. 2. the surface includes an aperture for passing the acoustic signal to the MEMS microphone. 3. the surface is a bumper cover or body panel of a vehicle. 4. the MEMS microphone is positioned to receive the acoustic signal as the acoustic signal passes to a side or around an edge of the surface. 5. the ultrasonic transducer and the MEMS microphone are part of a concealed assembly that further includes a controller configured to perform said processing. 6. the ultrasonic transducer is one of an array of ultrasonic transducers cooperatively transmitting the acoustic burst through the surface. 7. the acoustic burst is steerable by the array of ultrasonic transducers. 8. the ultrasonic transducer, the MEMS microphone, and the controller are each part of a concealed assembly that contacts a backside of the surface. 9. the ultrasonic transducer is further configured to convert acoustic signals into a second electrical receive signal. 10. the controller operates on the second electrical receive signal and the electrical receive signal from the MEMS microphone to detect the reflection. 11. the core logic is configured to provide a controllable phase shift between the second electrical receive signal and the electrical receive signal from the MEMS microphone for controllable directional sensitivity. 12. the core logic is configured to determine at least one of distance, azimuth, and elevation, to a reflector of the acoustic burst.

### BRIEF DESCRIPTION OF THE DRAWINGS

FIG. 1A is a perspective view of an illustrative vehicle equipped with hidden ultrasonic sensors.

FIG. 1B is an overhead view of an illustrative vehicle equipped with hidden ultrasonic sensors.

FIG. 2 is an isometric view of an illustrative ultrasonic sensor assembly.

FIG. 3 is a block diagram of an illustrative sensor controller.

FIG. 4 is a block diagram of an illustrative ADAS (advanced driver-assistance system).

FIG. 5 is a flow diagram of an illustrative sensing method using hidden ultrasonic sensors.

### DETAILED DESCRIPTION

It should be understood that the drawings and following description do not limit the disclosure, but on the contrary, they provide the foundation for one of ordinary skill in the art to understand all modifications, equivalents, and alternatives falling within the scope of the claim language.

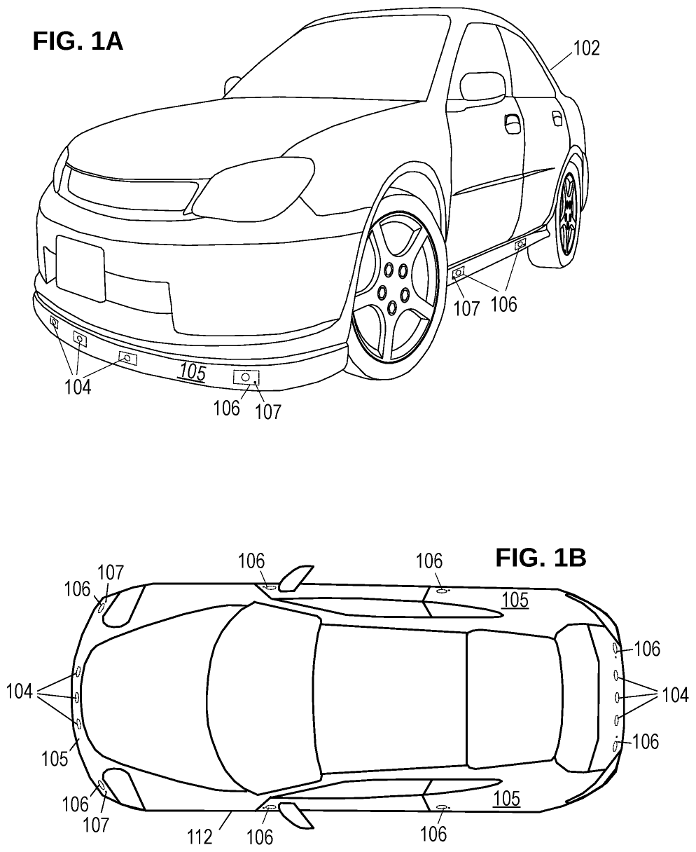

As an illustrative usage context, FIG. 1A shows a vehicle 102 equipped with a set of ultrasonic transducers 104 concealed by an overlying surface 105, which in this case is a cover of the vehicle bumper. Other placements are also contemplated, with the transducers being attached to (or otherwise abutting) the backside of fenders, quarter panels, hoods, trunk lids, doors, body panels, or elsewhere beneath the outer skin of the vehicle. Internal placements are also contemplated for, e.g., monitoring the vehicle cabin from behind any of the panels and shrouds forming the inner lining of the cabin. In addition to the ultrasonic transducers 104, the vehicle 102 includes one or more sensors 106 each having a MEMS (micro-electromechanical systems) microphone that can receive reflections of acoustic bursts emitted by the ultrasonic transducers 104. If part of a concealed sensor assembly, the MEMS microphone(s) may be positioned behind a small, e.g., 1-2 mm, hole 107 or acoustic window that permits passage of acoustic signals to the microphone. Such holes would be much smaller and much less obtrusive than the 2-4 cm apertures or acoustic windows often employed for conventional ultrasonic transducers. Alternatively, the MEMS microphone(s) may be positioned below or behind an edge of the surface, e.g., on the underside of a bumper, to receive acoustic signals that pass below or around the edge.

In certain contemplated embodiments, the ultrasonic transducers 104 are part of concealed sensor assemblies that each include a MEMS microphone, and similarly, the sensors 106 may each include an ultrasonic transducer concealed behind the overlying surface. In addition to detecting reflections of acoustic bursts emitted by ultrasonic transducers 104, the sensors 106 may detect reflections of acoustic bursts from their integrated ultrasonic transducers, and may further detect audible-range acoustic signals, e.g., sounds of a siren from an emergency vehicle. Where the ultrasonic transducers 104 are integrated into concealed sensor assemblies with a MEMS microphone, the integrated microphones may also be configured to detect reflections of acoustic bursts from the ultrasonic transducers 104 and may be configured to detect audible-range acoustic signals.

FIG. 1B is an overhead view of another illustrative vehicle 112 having an ADAS (advanced driver-assistance system) sensor arrangement with concealed ultrasonic transducers 104 and MEMS microphone sensors 106 hidden behind an overlying surface 105. Again, the MEMS microphone sensors 106 may also include ultrasonic transducers. The spaced arrangement of multiple sensors and ultrasonic transducers 104 enables transmitted acoustic bursts to be controllably steered and enables directional information to be derived for detected reflections of acoustic bursts and may improve determination of distance information. The illustrated sensor arrangement includes a MEMS microphone sensor 106 with an integrated ultrasonic transducer at each corner of the vehicle 112 and a spaced-apart pair of sensors 106 on each side of the vehicle. An array of ultrasonic transducers 104 is provided at the front of the vehicle 112 and a second array of ultrasonic transducers 104 is provided at the back of the vehicle. Other arrangements are contemplated and may provide various tradeoffs between cost, coverage, detection range, power consumption, and measurement rate.

Emitted bursts propagate outward from the vehicle until they encounter and reflect from an object or some other form of acoustic impedance mismatch. The reflected bursts return to the vehicle as “echoes” of the emitted bursts. The times between the emitted bursts and received echoes are indicative of the distances to the reflection points. In many systems, only one sensor transmits at a time, though all of the sensors may be configured to measure the resulting echoes. However independent simultaneous transmissions can be supported through the use of orthogonal waveforms, transmissions to non-overlapping detection zones, or transmissions with signatures that enable screening of any echoes from different transmitters.

Each of the transducers 104 and sensors 106 is concealed behind an overlying surface 105 with the possible exception of a small unobtrusive hole 107 over each MEMS microphone. When positioned behind such holes, on the side of the surface, or behind an edge of the surface, the MEMS microphones exhibit high sensitivity to audible and ultrasonic acoustic signals. The arrays of ultrasonic transducers may operate cooperatively to increase the effective acoustic burst amplitude and to enhance directionality of the emitted acoustic burst. Note that the cooperative operation can be achieved with synchronized operation of the transducers, and the enhanced directionality can be achieved with a controllable phase shift between the emitted signals. The transducers in each array may preferably operate concurrently, but with proper processing such concurrent operation is not a requirement.

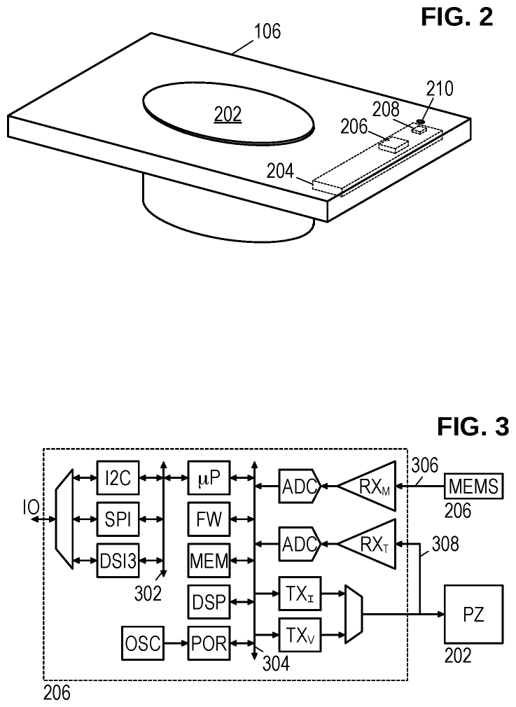

FIG. 2 is an isometric view of an illustrative sensor assembly 106 having an ultrasonic transducer 202 that abuts, contacts, attaches to, or otherwise mechanically couples with the backside of an overlying surface 105 (FIGS. 1A, 1B) to transmit acoustic bursts through the surface. The sensor assembly 106 includes a substrate 204 such as a PCB (printed circuit board) with the control electronics for the sensor assembly. Mounted on the substrate 204 is a sensor controller 206 and a MEMS microphone 208. A hole 210 is provided in the assembly case to facilitate detection of acoustic signals by the MEMS microphone 210. Hole 210 may be aligned with an unobtrusive hole or acoustic window 107 in the overlying surface, or the assembly 106 may be configured to position the MEMS microphone 208 on a side of the overlying surface or behind an edge of the overlying surface where it can be sensitive to acoustic signals without being obtrusive. In some contemplated sensor assemblies, the MEMS microphone 208 is displaced vertically from the ultrasonic transducer 202 and may operate cooperatively with the transducer to enable direction of arrival (DoA) detection from which the reflector's elevation angle may be estimated. Alternatively, two vertically spaced MEMS microphones can be used for this purpose. In a similar fashion, the MEMS microphone may be displaced horizontally from the ultrasonic transducer to enable estimation of the reflector's azimuthal angle. Two horizontally spaced MEMS microphones can alternatively be used for this purpose. Some contemplated sensor assemblies have multiple MEMS microphones that provide a horizontal and a vertical displacement relative to the transducer or to each other, enabling estimation of both elevation and azimuthal angles.

FIG. 3 shows a block diagram of an illustrative sensor controller 206. It employs IO (input and output) pins that are multiplexed to a selected one of various IO protocol modules. Modules are shown for the I²C (inter-integrated circuit), SPI (serial peripheral interface), and DSI3 (3rd generation of distributed systems interface) communications bus protocols, but these are just nonlimiting examples. Other contemplated protocols include those set forth in the LIN, CAN, and SENT standards. An IO bus 302 couples the various IO protocol modules to an embedded microprocessor (μP). An AMBA (advanced microcontroller bus architecture) bus such as, e.g., an AMB-Lite (simplified advanced high-performance bus), may be used to couple the embedded microprocessor to various other functional blocks of the sensor controller 206. Such blocks may include, e.g., a nonvolatile firmware (FW) memory, a volatile working memory (MEM), a digital signal processor (DSP), a power-on reset (POR) module, an ADC (analog to digital converter) for a microphone signal receiver (RX_{M}), a second ADC for a transducer signal receiver (RX_{T}), a drive-current transmitter (TX_{I}), and a drive-voltage transmitter (TX_{V}). (The transmitters generate the drive signal for the ultrasonic transducer as a controlled current or controlled voltage, respectively.) A multiplexer may couple a selected one of the transmitters to output pins for driving the transducer 202. FIG. 3 further shows an embedded oscillator (OSC) that generates one or more clock signals for the various other blocks, optionally including a carrier frequency for the transmitters and receivers. The POR module may control distribution of the clock signals to enable a sleep mode for unneeded components and other power saving features.

The IO pins couple the sensor controller 206 directly or indirectly (e.g., via a DSI3 bus master) to an ECU (electronic control unit). The ECU may communicate commands to each of the sensor controllers to, e.g., set values for the sensors' various configuration parameters, to initiate transmission of acoustic bursts, and to collect signal data or other measurement results. The microprocessor in each sensor controller operates in accordance with firmware and stored configuration parameters to parse commands from the ECU and carry out the appropriate operations, including the transmission of acoustic bursts and reception of acoustic signals.

In various implementations, use is made of chirp-modulated signals, for instance a linear frequency modulated (“LFM”) chirp. A chirp is a pulse that changes frequency during transmission. An up-chirp is a signal pulse that increases in frequency during transmission, and a down-chirp is a signal pulse that decreases in frequency during transmission. For clarity, the examples used herein will consider a linear increase or decrease, however in various implementations the increase or decrease is not linear. The echo of a chirp may be compressed in a correlator without introducing much or any correlation noise. As such, peak detection of the echo is eased without decreasing time resolution. Additionally, LFM chirps withstand Doppler frequency shift without, or with a minimum of, any increase in correlation noise. LFM chirps can be used as transmit pulses for measuring a distance and direction to an obstacle, or object, situated in the sensing range of a sensor system.

In other implementations, use is made of AM (amplitude-modulated) signals, for instance a shaped pulse of a fixed-frequency carrier. AM signaling mode may enable the use of shorter bursts (e.g., on the order of 200 to 300 microseconds), reducing transmission time and increasing sensitivity to nearby obstacles. Other implementations may employ pulses with modulated carriers, e.g., modulated with binary phase shift keying (BPSK). For sake of clarity, the term “burst” as used herein refers to an AM (fixed frequency), BPSK (modulated), or chirp (swept frequency) pulse, which may be one of a series of bursts created by driving a piezoelectric element or other ultrasonic transducer. Chirp-modulated pulses may have a longer duration than a typical AM pulse, for instance more than 1 millisecond, such as in the range of 2-3 milliseconds. It is noted here that burst lengths can be varied, with shorter bursts being used to facilitate detection of nearby obstacles and longer bursts being used to increase burst energy (and echo energy) for more distant obstacles. Burst lengths for detecting nearby obstacles may be half or perhaps a quarter of the burst lengths used for more distant obstacles. The sensor may be switched between modes for different detection distances.

Although it is deemed particularly useful to systematically vary a characteristic frequency (e.g., the starting frequency or, equivalently, the center or ending frequency) of the chirp-modulated pulses in a series, such frequency variation can also be applied to the carrier frequency of the AM pulses in a series. The frequency variation can be expressed for each pulse as a frequency displacement from a nominal characteristic frequency (e.g., a nominal starting frequency or nominal carrier frequency).

To transmit an acoustic burst, the microprocessor instructs a selected transmitter to drive the output pins for the ultrasonic transducer, which are coupled to a piezoelectric element PZ. A transformer and/or resonance tuning network may be provided for voltage amplification and control of the transducer's resonant frequency. The transmitters may accept a carrier frequency signal from the oscillator with a nominal frequency of, e.g., 50 kHz. The transmitter may use the carrier frequency signal to generate a series of AM (amplitude modulated) or chirp pulses, each pulse corresponding to an acoustic burst. An example of a chirp pulse may be a pulse having a frequency swept upward from 7 kHz below the carrier frequency to 7 kHz above the carrier frequency (up-chirp). A down chirp may alternatively be employed, with the frequency being swept linearly downward rather than upward. In some contemplated implementations, the transmitter provides a custom pattern of frequency offsets to the acoustic bursts to serve as a unique signature for that ultrasonic transducer.

To receive an acoustic signal, the microprocessor instructs one or both ADCs to digitize the electrical receive signal from the MEMS microphone 206 and/or the piezoelectric element 202. The digitized signals may be provided directly to the DSP for real time processing or buffered in memory for later processing by the DSP or by the ECU. To reduce IO bandwidth requirements, the DSP may implement data compression to reduce the number of bits needed to represent the ZIF IQ data or to represent the magnitude of the baseband signals. To even further reduce bandwidth requirements, the DSP may perform on-chip processing for peak detection and distance estimation. Various suitable processing techniques for detecting reflections of the acoustic burst are known in the art, including co-owned US Patent Publication 2024/0069192 “Motion-compensated distance sensing with concurrent up-chirp down-chirp waveforms”, which is hereby incorporated herein by reference.

As the received electrical signals are typically in the millivolt or microvolt range, the receivers RX_{M}, RX_{T} may include amplifiers to buffer and amplify the signal from the receive terminals. Analog or digital mixers may be included to down convert the receive signals to baseband for further filtering and processing by the DSP. The mixer is in one implementation an in-phase/quadrature (I/Q) digital mixer giving Zero Intermediate Frequency (ZIF) IQ data as its output. (Though the term “ZIF” is used herein, the down converted signal may in practice be a low intermediate frequency or “near-baseband” signal.)

The DSP applies programmable methods to acquire the receive signals and to detect any echoes and measure their parameters such as time-of-flight (ToF), direction of arrival (DoA), duration, and peak amplitude. Such methods may employ threshold comparisons, minimum intervals, peak detections, zero-crossing detection and counting, noise level determinations, and other customizable techniques tailored for improving reliability and accuracy. Notably, the peak detection process itself has variations, with some variations performing rising edge detection, falling edge detection, or detection of the peak maximum. Processing for nearby obstacle detection may be performed entirely in the controller 206 or may be shared with or delegated to an ECU or host processor, which receives certain data via the communications bus as previously described.

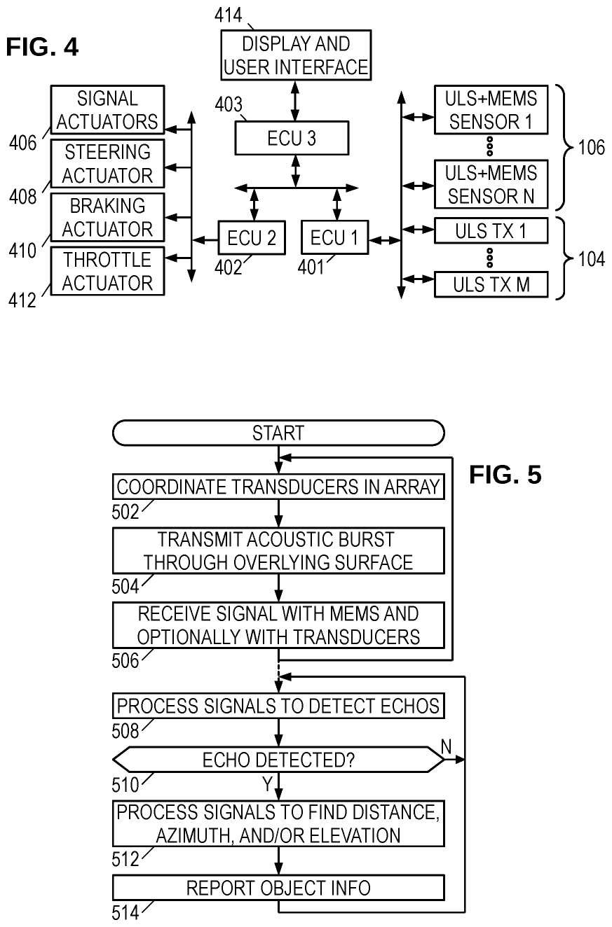

FIG. 4 shows a set of interconnected ECUs (electronic control units) 401-403 organized in a hierarchical bus topology. Of course, other topologies including serial, parallel, star, and ring topologies, are also suitable and contemplated for use in accordance with the principles disclosed herein. A first ECU 401 is coupled to the array(s) of ULS transducers 104 and MEMS microphone sensors 106, which may also include ULS transducers. To provide automated parking or driving assistance, a second ECU 402 may connect to a set of actuators such as a turn-signal actuator 406, a steering actuator 408, a braking actuator 410, and throttle actuator 412. The third ECU 403 may couple to a user-interactive interface 414 to accept user input and provide a display of the various measurements and system status. Using the interface, sensors, and actuators, ECUs 401-403 may provide automated parking, assisted parking, lane-change assistance, obstacle and blind-spot detection, and other desirable features.

FIG. 5 is a flow diagram of an illustrative sensing method that employs MEMS microphones. Though MEMS microphones are not suited for generating acoustic bursts, their small size, high sensitivity, and decoupling from acoustic burst generators enables the detection of reflections of acoustic bursts from hidden ULS transducers despite the attenuation and extended transducer reverberation potentially caused by the overlying surface. The sensing method may be implemented by the sensor controller, by the ECU, or the method steps may be distributed among multiple components of the sensing system. The latter two implementations may be preferred when the operations of multiple transducer and sensor assemblies are being coordinated.

If a single sensor assembly implements the method, block 502 may be skipped. Otherwise, an ECU coordinates the operation of the various sensor and transducers that are to cooperate in an obstacle detection/monitoring measurement. Such coordination may include setting measurement parameters (e.g., carrier frequency, burst duration, transmitter and receiver selection), timing synchronization, and a trigger signal or measurement initiation command.

In block 504, the selected ULS transducer(s) each generate an acoustic burst that propagates through the overlying surface and beyond, towards a region of interest. The acoustic burst reflects from any obstacles within range, and the reflections propagate back to the sensing array, which includes one or more selected MEMS microphones and, optionally, the transmitting ULS transducers or other selected ULS transducers. In block 506, the selected receivers capture the electrical receive signal(s) from the sensing array. Blocks 502-506 may then be repeated with the same or different arrangements of transmitters and receivers to collect additional receive signals.

As the electrical receive signals are captured, the ECU and/or sensor controller may process them in block 508, applying elsewhere-described techniques for detecting echoes and determining corresponding obstacle distances. Such techniques typically include dynamic gain, filtering, correlation, magnitude determination, threshold comparisons, and combining of multiple measurements to enhance signal to noise ratio and resistance to transient events. In block 510, the ECU and/or sensor controller determine whether an echo has been detected, e.g., by determining whether the combined signal exceeds a threshold. If not, the process returns to block 508 to process the next receive signal. If so, then in block 512 the ECU and/or sensor controller determines at least one of a distance (or equivalently, a travel time between transmission and echo). The ECU and/or sensor controller may further determine a direction to the reflector, e.g., using relative phase information to determine a direction of arrival azimuth and/or elevation. Other suitable direction-finding techniques are available in the open literature. In block 514, the ECU and/or sensor controller may report the detected echo information to another ECU or to the user to enable the obstacle to be avoided or otherwise taken into account as part of the ADAS system functionality.

Though the operations shown and described in FIG. 5 are treated as being sequential for explanatory purposes, in practice the method may be carried out by multiple system components operating concurrently and perhaps even speculatively to enable out-of-order operations. The sequential discussion is not meant to be limiting.

The disclosed system may advantageously provide cost-efficient implementations of concealed ultrasonic sensing because it does not require sophisticated damping materials for the ULS transducers. The MEMS microphones may at least partly obviate potential reverberation issues that would otherwise be faced when using the ULS transducers as detectors. Moreover, their small size and high sensitivity enable unobtrusive placements and may reduce the number of sensors needed for various ADAS system features. MEMS microphones are also inexpensive and consume minimal power. Preliminary tests indicate the disclosed hidden transducer and sensor arrangement may offer in excess of 5 meters in detection range without any visible effect on the vehicle aesthetics. While park assist, automatic parking, door protection, and kick-to-open are contemplated vehicle features implementable with the disclosed sensors, other potential uses include sensing of passengers and intrusion detection with concealed sensors in the vehicle cabin. Non-vehicle uses may include security monitoring (e.g., in display cases) and traffic monitoring (e.g., at building entrances).

Numerous modifications, equivalents, and alternatives will become apparent to those skilled in the art once the above disclosure is fully appreciated. It is intended that the following claims be interpreted to embrace all such modifications, equivalents, and alternatives where applicable.

1. A sensing method that comprises:
transmitting an acoustic burst through a surface over an ultrasonic transducer;
receiving an acoustic signal with a MEMS (micro-electromechanical systems) microphone, the MEMS microphone representing the acoustic signal as an electrical receive signal; and
processing the electrical receive signal to detect a reflection of the acoustic burst.

2. The sensing method of claim 1, wherein the surface has no opening or acoustic window for conveying the acoustic burst.

3. The sensing method of claim 1, wherein the surface includes an aperture for passing the acoustic signal to the MEMS microphone.

4. The sensing method of claim 3, wherein the surface is a bumper cover or body panel of a vehicle.

5. The sensing method of claim 3, wherein the MEMS microphone is positioned to receive the acoustic signal as the acoustic signal passes to a side or around an edge of the surface.

6. The sensing method of claim 1, wherein ultrasonic transducer and the MEMS microphone are part of a concealed assembly that further includes a controller configured to perform said processing.

7. The sensing method of claim 1, wherein said ultrasonic transducer is one of an array of ultrasonic transducers cooperatively transmitting the acoustic burst through the surface.

8. The sensing method of claim 7, wherein the acoustic burst is steerable by the array of ultrasonic transducers.

9. The sensing method of claim 1, further comprising:
receiving a second acoustic signal with the ultrasonic transducer, the ultrasonic transducer conveying the second acoustic signal as a second electrical receive signal,
wherein the processing determines a distance to a reflector based at least in part on the second electrical receive signal and the electrical receive signal from the MEMS microphone.

10. An ADAS (advanced driver-assistance system) comprising:
an ultrasonic transducer configured to transmit an acoustic burst through a surface over the ultrasonic transducer;
a MEMS (micro-electromechanical systems) microphone configured to convert a received acoustic signal into an electrical receive signal; and
a controller configured to detect a reflection of the acoustic burst based on the electrical receive signal.

11. The ADAS of claim 10, wherein the surface has no opening or acoustic window for conveying the acoustic burst.

12. The ADAS of claim 10, wherein the surface includes an aperture for passing the acoustic signal to the MEMS microphone.

13. The ADAS of claim 12, wherein the surface is a cover of a vehicle bumper.

14. The ADAS of claim 12, wherein the MEMS microphone is positioned to receive the acoustic signal as the acoustic signal passes to a side or around an edge of the surface.

15. The ADAS of claim 10, wherein ultrasonic transducer, the MEMS microphone, and the controller are each part of a concealed assembly that contacts a backside of the surface.

16. The ADAS of claim 10, wherein said ultrasonic transducer is one of an array of ultrasonic transducers configured to cooperatively transmit the acoustic burst through the surface.

17. The ADAS of claim 10, wherein the ultrasonic transducer is further configured to convert acoustic signals into a second electrical receive signal, and wherein the controller operates on the second electrical receive signal and the electrical receive signal from the MEMS microphone to detect the reflection.

18. A sensor controller that comprises:
a transmitter configured to drive an ultrasonic transducer to transmit an acoustic burst;
a receiver configured to receive an electrical receive signal from a MEMS microphone representing an acoustic signal; and
a processor configured to process the electrical receive signal to detect a reflection of the acoustic burst.

19. The sensor controller of claim 18, further comprising:
a second receiver configured to receive a second electrical receive signal from the ultrasonic transducer,
wherein the processor is configured to detect the reflection based on each of the second electrical receive signal and the electrical receive signal from the MEMS microphone.

20. The sensor controller of claim 19, wherein the processor is configured to provide a controllable phase shift between the second electrical receive signal and the electrical receive signal from the MEMS microphone for controllable directional sensitivity.
